(19) United States
(12) Patent Application Publication
(10) Pub. No.: US 2026/0005491 A1
(43) Pub. Date: Jan. 1, 2026

(54) LASER DEVICE AND MANUFACTURING METHOD

(71) Applicant: Fraunhofer-Gesellschaft zur Förderung der angewandten Forschung e.V., München (DE)

(72) Inventors: Gayatri VASUDEVAN RAJESWARI, Berlin (DE); Martin MÖHRLE, Berlin (DE)

(73) Assignee: Fraunhofer-Gesellschaft zur Förderung der angewandten Forschung e.V., München (DE)

(21) Appl. No.: 18/761,292

(22) Filed: Jul. 1, 2024

(51) Int. Cl. H01S 5/12; H01S 5/028; H01S 5/125

(52) U.S. Cl. CPC H01S 5/1206; H01S 5/028; H01S 5/125

(57) ABSTRACT

Higher modulation speed is achieved for a laser device comprising: an active layer structure between a semiconductor substrate and a grating structure configured for manipulation, comprising a common active layer for generation of laser light; a first facet spatially adjacent to one end of and a second facet spatially adjacent to an opposing end of the active layer structure, the first facet emitting laser light, the second facet being opposite the first, both comprising anti-reflection coating; the grating structure comprising spatially adjacent integral grating sections; a cladding structure for optically confining the laser light and adapted for arranging the grating structure between the active layer and the cladding structure; a DFB structure having a first grating section, at least one DBR structure having a second grating section, the first and second grating sections sharing the common active layer for at least the integral grating sections; the DFB structure comprising a first optical function as lasing function and the at least one DBR structure comprising a second one as optical feedback.

### TECHNICAL FIELD

The present application relates to a laser device and its method of manufacture, the laser device such as, but not exclusively, distributed feedback and distributed Bragg reflector lasers sharing a common active layer. The present application also relates to methods for generating laser light.

### BACKGROUND OF THE INVENTION

For optical data transmission in telecom systems, within data centers or within high performance computing systems, high speed transmitter components are needed. High speed distributed feedback (DFB) lasers, in particular in the o-band wavelength range, are key components for these applications.

Within the last ten years, significant R&D effort has been carried out in order to increase the modulation speed of DFB lasers by optimizing the InGaAlAs MQW active layer and the DFB-grating regarding high carrier-photon resonance (CPR), and in addition to that by reducing series resistance and parasitic capacitance of the lasers. In this way, DFB lasers with a frequency bandwidth of up to 30 GHz at room temperature operation were achieved.

However, recent advancements have pushed the boundaries further, with some DFB lasers achieving frequency bandwidths of 40 GHz or higher [1.1], [1.2]. These advancements have been made using conventional methods to enhance CPR. One approach involves increasing the ratio between the optical confinement factor and the mode field diameter [1.1]. Another approach utilizes membrane DFB with a buried sapphire layer on a silicon substrate [1.2].

Various industrial applications require more than 100 Gbps bitrate for data transmission. Even though existing electro-absorption modulated DFBs exhibit a good performance at 100 Gbps, non-return-to zero (NRZ) format, they are not a cost effective and energy efficient solution. Therefore, alternative approaches are being explored to further increase the modulation bandwidth of directly modulated lasers (DML).

One such technique is detuned loading, where the lasing mode is positioned at the longer wavelength side of the reflection spectrum [1.4], [1.7]. Another technique involves utilizing a second resonance, called photon-photon resonance (PPR), in addition to CPR to enhance the speed of the laser [1.3], [1.4], [1.5], [1.6], [1.7]. This requires a coupled-cavity laser structure with feedback. This technique not only offers the potential for higher-speed data transmission but also allows for low chirp modulation compared to EMLs.

Several studies have shown different coupled-cavity laser variants including passive feedback lasers [1.3], dual DFBs [1.4], distributed reflector (DR) laser [1.5], DFB+R laser [1.6], and directly modulated membrane DFB lasers on SiC substrate [1.7]. So far the highest speed is reported by [1.7] achieving >110 GHz at 25° C. and 74 GHz at 85° C. using directly modulated membrane DFB laser on SiC substrate. However, such membrane lasers suffer from a very low optical output power <<1 mW so that for a lot of applications they cannot be used.

Most of the reported variants so far involve some percentage reflection coating in at least one of its facets. Hence, these variants suffer from very low device yield, making them neither suitable for array compatibility nor for volume production. So far only [1.8] has shown an array of two devices achieving a modulation bandwidth of 60 GHz in each channel. [1.8] used a membrane DML on SiO₂/Si, with distributed Bragg reflector (DBR) grating on both sides of the DFB. Here, a uniform grating DFB is used and the DBR on the rear side (DBR-r) ensure a stable single mode operation. The DBR on the front side (DBR-f) selects the longer wavelength mode and provides optical feedback, thus exploiting the properties of detuned loading and PPR effect. The DBR grating in this design is realized employing a butt-joint grown passive waveguide which contributes to an arbitrary phase condition between the DFB and DBR. Therefore, even though the reflective coating on the facets is avoided, due to the arbitrary phase between the gratings, the possibility of high yield array is very limited.

Furthermore, a conventional DFB design featuring an additional active distributed reflector (ADR) with the same waveguide core as the DFB laser has been demonstrated [1.9]. In this configuration, the ADR effectively replaces the high reflectivity (HR) coating on the rear facet of the DFB. A modulation bandwidth of 24 GHz is achieved. However, no photon-photon resonance PPR effect is used here.

Recently, [1.10] conducted a study on a variant of dual DFB configuration, in which two DFBs are separated by a passive section grown through a butt-joint process. This device leverages the PPR effect and achieves speeds of up to 72 Gbps when cooled and 40 Gbps when uncooled. However, in this configuration, the grating did not have a fixed phase condition leading to limited yield of the devices demonstrating the PPR effect despite the facets being coated with anti-reflection (AR) coatings.

Therefore, there is a particular need for providing laser devices having higher modulation speeds, high device yield and improved array compatibility in either cooled or uncooled operation condition.

Such a need is fulfilled by a laser device according to independent claim 1 and a laser device according to independent claim 18, a method for manufacturing a laser device according to claim 19 and a method for generating laser light according to claim 20. Further, specific implementations of the present inventive concept for the laser device according to independent claim 1 are defined in the dependent claims.

### SUMMARY

According to an embodiment, a laser device comprises an active layer structure arranged between a semiconductor substrate and a grating structure. The active layer structure comprises a common active layer configured for generation of laser light and the grating structure is configured for manipulating the generation. The laser device further comprises a first facet arranged spatially adjacent to one end of the active layer structure and second facet arranged spatially adjacent to an opposing end of the active layer structure. The first facet is configured for emitting the laser light. The first facet and the second facet comprise an anti-reflection coating. The grating structure comprises a plurality of integrally formed grating sections arranged spatially adjacent to each other. The laser device further comprises a cladding structure configured for optically confining the laser light. The cladding structure is adapted such that the grating structure is arranged between the active layer structure and the cladding structure. The laser device further comprises a DFB structure having a first grating section of the grating structure. The laser device further comprises at least one DBR structure having a second grating section of the grating structure. The first grating section and the second grating section share the common active layer being common for at least the plurality of integrally formed grating sections. The DFB structure comprises a first associated optical function as a lasing function. The at least one DBR structure comprises a second associated optical function as an optical feedback.

Thus, the laser device of the present concept using the plurality of integrally formed grating sections, in sharing the common active layer between them, have a pre-defined, or fixed, phase condition. The pre-defined, or fixed, phase condition between the integrally formed grating sections across the common active layer is ensured by continuous, or single, grating writing using a single grating writing field. Therefore, the laser device of the present concept achieves a higher device yield.

The laser device of the present concept achieves that the phase mismatches arising from facet coatings are avoided. This is realized by each of the first facet and the second facet comprising an anti-reflection coating. The AR coatings do not permit an arbitrary phase condition in the laser device. Thus, the laser device avoids common phase mismatches arising from facet coatings and has improved array-compatibility.

The laser device of the present disclosure uses a DFB structure which performs the lasing function and at least one DBR structure which provides optical feedback, both structures having the common active layer, to obtain the PPR effect. This leads to an increase in the modulation bandwidth, for instance, higher modulation bandwidths reaching more than 100 GHz. Therefore, the laser device according the present inventive concept provides dual DFB lasers (DFB+DBR) with common active layer, and feasibly multiple DFB lasers with common active layer, having improved modulation speed and enhanced array-compatibility.

According to an embodiment, the grating structure further comprises a grating-free section configured for providing passive feedback of the laser light, wherein the grating-free section is arranged between two grating sections of the grating structure sharing the common active layer.

According to an embodiment, the grating structure is obtained by a common or single writing process. This single writing process may comprise using any of a common or single e-beam, a common or single stepper based lithographic process, or a common or single holographic writing process.

According to an embodiment, the grating structure comprise at least one phase shift element forming a part of one of the grating sections configured for applying a predefined phase shift to light travelling through the at least one phase shift elements.

According to an embodiment, the laser device comprises an electrode arrangement; wherein the DFB structure is arranged between a first pair of electrodes, wherein the first pair of electrodes is associated with the DFB structure to adapt the optical function of the DFB structure.

According to an embodiment, the DFB structure is configured to obtain a first resonance having a first frequency of a carrier-photon resonance, CPR.

According to an embodiment, the at least one DBR structure is arranged between a second pair of electrodes, wherein the second pair of electrodes is associated with the at least one DBR structure to adapt the optical function of the at least one DBR structure.

According to an embodiment, the at least one DBR structure is configured to obtain a second resonance having a second resonance frequency of a photon-photon resonance, PPR.

By this measure, the laser device that would comprise a DFB structure and at least one DBR structure, uses the PPR effect permitting an enhancement of modulation bandwidth.

According to an embodiment, the semiconductor substrate comprises at least one of InP, GaAs, Si, SiC, SiNx and thin film lithium niobate. The process of providing the semiconductor substrate with at least one of InP, GaAs, Si, SiC, SiNx and thin film lithium niobate may comprise a micro-transfer printing process or a process involving membrane lasers.

According to another aspect of the present inventive concept, a laser device comprises an active layer structure arranged between a semiconductor substrate and a grating structure. The active layer structure comprises a common active layer comprising aluminum (e.g., the common active layer comprising InGaAlAs), the common active layer is configured for a generation of laser light and the grating structure is configured for manipulating the generation. The laser device further comprises a first facet arranged spatially adjacent to one end of the active layer structure and a second facet arranged spatially adjacent to an opposing end of the active layer structure. The first facet is configured for emitting the laser light and the second facet is opposite to the first facet. The first facet and the second facet each comprise an anti-reflection coating. The active layer structure further comprises two integrated passive sections arranged spatially adjacent to opposing ends of the common active layer, and the first facet and the second facet. By this measure, the laser device with the help of two integrated passive sections prohibits aluminum based oxidative processes at the facets. This allows the laser device to have aluminum-free facets, since the passive sections comprise materials lacking aluminum, thereby improving its reliability.

In accordance with another aspect of the present inventive concept, a method for manufacturing a laser device comprises arranging an active layer structure between a semiconductor substrate and a grating structure. Such that the active layer structure comprises a common active layer configured for generation of laser light, the grating structure is configured for manipulating the generation. Such that the grating structure comprises at least a plurality of integrally formed grating sections arranged spatially adjacent to each. The method further comprises adapting a cladding structure configured for optically confining the laser light. Such that the grating structure is arranged between the active layer structure and the cladding structure. The method further comprises arranging a first facet spatially adjacent to one end of the active layer structure and a second facet spatially adjacent to an opposing end of the active layer structure. Such that the first facet is configured for emitting the laser light, the second facet is opposite to the first facet, and the first facet and the second facet each comprise an anti-reflection coating. The method further comprises arranging a DFB structure having a first grating section of the grating structure. The method further comprises arranging at least one DBR structure having a second grating section of the grating structure. Such that the first grating section of the DFB structure and the second grating section of the at least one DBR structure share the common active layer being common for at least the plurality of integrally formed grating sections.

In accordance with another aspect of the present inventive concept, a method for generating laser light comprises arranging an active layer structure comprising a common active layer between a semiconductor substrate and a plurality of integrally formed grating sections of a grating structure, the common active layer configured for generating the laser light and the grating section is configured for manipulating the generation.

Thus, embodiments enable manufacturing a laser device such as, but not exclusively limited to, dual DFB lasers (DFB+DBR) with common active layer, with higher modulation speed and enhanced array compatibility leveraging the PPR effect, resulting in significantly reduced overall production costs, in comparison to conventional PPR based lasers.

In the following description, embodiments are discussed in detail, however, it should be appreciated that the embodiments provide many applicable concepts that can be embodied in a wide variety of the field of laser devices. The specific embodiments discussed are merely illustrative of specific ways to implement and use the present concept, and do not limit the scope of the embodiments. In the following description of embodiments, the same or similar elements or elements that have the same functionality are provided with the same reference sign or are identified with the same name, and a repeated description of elements provided with the same reference number or being identified with the same name is typically omitted. In the following description, a plurality of details is set forth to provide a more thorough explanation of embodiments of the disclosure.

However, it will be apparent to one skilled in the art that other embodiments may be practiced without these specific details. In other instances, well-known structures and devices are shown in diagram form rather than in detail in order to avoid obscuring examples described herein. In addition, features of the different embodiments described herein may be combined with each other, unless specifically noted otherwise.

### BRIEF DESCRIPTION OF THE DRAWINGS

Embodiments of the present inventive concept will be detailed subsequently referring to the appended drawings, in which:

FIG. 1 shows a schematic cross-sectional illustration of a laser device according to an embodiment of the present inventive concept;

FIG. 2 shows a schematic cross-sectional illustration of a laser device according to another embodiment of the present inventive concept, wherein the laser device comprises a DFB structure and a DBR structure;

FIG. 3 shows a schematic cross-sectional illustration of a laser device according to another embodiment of the present inventive concept, wherein the laser device comprises a grating structure with a grating-free section;

FIG. 4 shows a schematic cross-sectional illustration of a laser device according to another embodiment of the present inventive concept, wherein the laser device comprises a semiconductor optical amplifier section;

FIG. 5 shows a schematic cross-sectional illustration of a laser device according to another embodiment of the present inventive concept, wherein the laser device comprises two integrated passive sections;

FIG. 6 shows a schematic cross-sectional illustration of a laser device according to another embodiment of the present inventive concept, wherein the laser device comprises a DFB section and two DBR sections;

FIG. 7 shows a schematic block diagram of a method for manufacturing a laser device according to an embodiment of the present inventive concept; and

FIG. 8 shows a schematic block diagram of a method for generating laser light according to an embodiment of the present inventive concept.

### DETAILED DESCRIPTION OF THE INVENTION

Equal or equivalent elements or elements with equal or equivalent functionality are denoted in the following description by equal or equivalent reference numerals even if occurring in different figures.

In the following description, a plurality of details is set forth to provide a more thorough explanation of embodiments of the present invention. However, it will be apparent to those skilled in the art that embodiments of the present invention may be practiced without these specific details. In other instances, well known structures and devices are shown in block diagram form rather than in detail in order to avoid obscuring embodiments of the present invention. In addition, features of the different embodiments described hereinafter may be combined with each other, unless specifically noted otherwise.

For facilitating the description of the different embodiments, the drawings comprise a Cartesian coordinate system x, y, z, wherein the x-y-plane corresponds, i.e. is parallel, to a cross section of a laser device, wherein the direction vertically up with respect to the reference plane (x-y-plane) corresponds to the “+z” direction, and wherein the direction vertically down with respect to the reference plane (x-y-plane) corresponds to the “−z” direction. In the following description, the term “lateral” means a direction parallel to the x-direction, the term “vertical” means a direction parallel to the y-direction and the term “longitudinal” means a direction parallel to the z-direction.

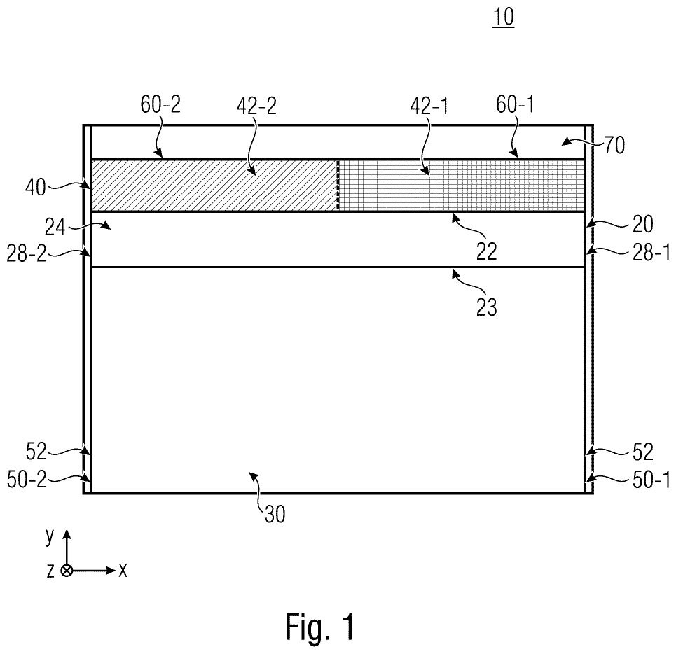

A laser device 10, in accordance with an aspect of the inventive concept of the present disclosure, is now described with respect to FIG. 1.

FIG. 1 exemplarily shows a schematic cross-sectional view (parallel to an x-y plane) of the laser device 10 comprising an active layer structure 20, a semiconductor substrate 30, a grating structure 40, a first facet 50-1, a second facet 50-2, a cladding structure 70, a DFB structure 60-1 and at least one DBR structure 60-2 sharing a common active layer 24 of the active layer structure 20.

As seen in FIG. 1, the active layer structure 20 is arranged between the semiconductor substrate 30 and the grating structure 40. That is, the active layer structure 20 is sandwiched between the semiconductor substrate 30 and the grating structure 40 allowing further layers, such as a buffer layer/waveguide which is not shown in FIG. 1 and is understandable to persons skilled in the art, between the active layer structure 20 and the semiconductor substrate 30 on the one hand and the active layer structure 20 and the grating structure 40 on the other hand. In particular, FIG. 1 shows that the grating structure 40 is sandwiched between the active layer structure 20 and the cladding structure 70. In other words, the grating structure 40 may be spatially neighbouring the cladding structure 70 and the active layer structure 20 may be spatially neighbouring the grating structure 40 along a one face 22. The active layer structure may spatially neighbour the semiconductor substrate 30, allowing possibly further layers in between, along an opposite face 23, being opposite to its face 22. In particular, the active layer structure 20 may extend laterally, along the x-direction, such that a lateral width of the active layer structure 20 coincides with a lateral width of the semiconductor substrate 30, a lateral width of the grating structure 40 and a lateral width of the cladding structure 70.

According to an embodiment, whilst not excluding other suitable materials, a preferred semiconductor substrate may comprise at least one of InP, GaAs, Si, SiC, SiNx and thin film lithium niobate. The process of providing the semiconductor substrate with at least one of InP, GaAs, Si, SiC, SiNx and thin film lithium niobate may comprise a micro-transfer printing process or a process involving membrane lasers.

The active layer structure 20 comprises the common active layer 24 configured for a generation of laser light. The common active layer 24 is common for the DFB structure and at least one, a subset of or preferably all of the DBR structures of the laser device 10. It is shown in FIG. 1 that ends 28-1, 28-2 of the active layer structure 20 may coincide with ends 28-1, 28-2 of the common active layer 24, in contrary to other aspects and embodiments of the inventive concept described in the present disclosure.

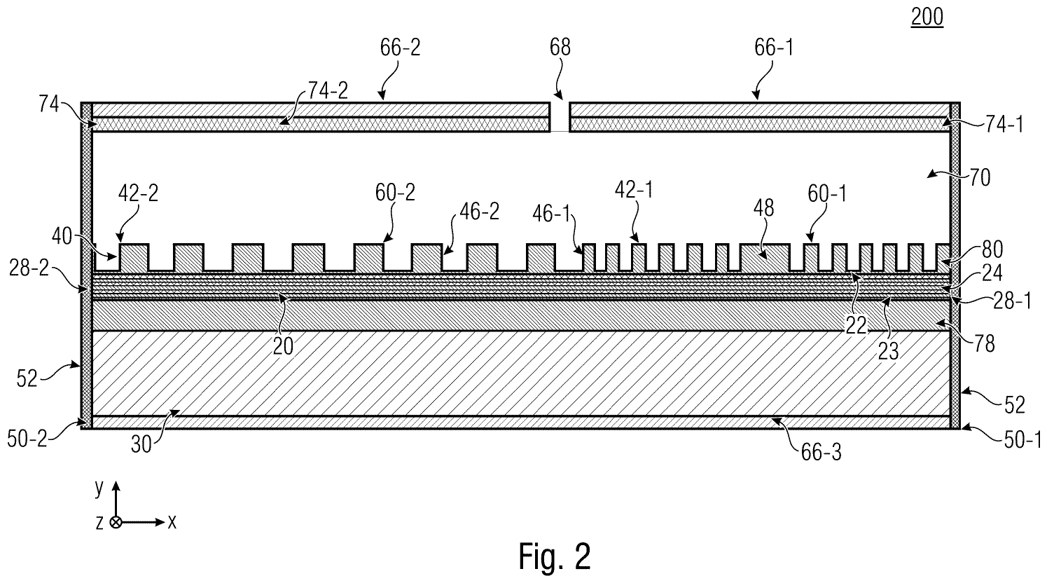

As will also be described in more detail further below, in particular with respect to FIGS. 2-6, it is feasible that the common active layer 24 is itself a layer stack, structured comprising a certain multiple quantum well (MQW) structure and/or sandwiched between certain waveguide layers.

According to an embodiment, the active layer may comprise at least one of an InGaAsP (QW)/InGaAsP (barrier) multi-quantum well, MQW, an InGaAlAs (QW)/InGaAlAs (barrier) MQW, an InGaAsP (QW)/InGaAlAs (barrier) MQW, InAs multi-quantum dot, MQD, and an InAs MQDash material.

The grating structure 40 of the laser device 10 is configured for manipulating the generation of the laser light. This manipulation may comprise a modification of optical characteristics of the laser light provided by the common active layer 24. For instance, the modification of optical characteristics of the laser light may comprise changing the optical gain of the laser light, exciting modes of the laser light to permit resonances or modifying phases of the laser light.

The grating structure 40 comprises a plurality of integrally formed grating sections 42-1, 42-2, . . . arranged spatially adjacent to each other allowing further sections to be comprised between them.

According to an embodiment, the grating structure 40 may be obtained by a common or single writing process. This single writing process may comprise using any of, but not limited to or exclusively, a common or single e-beam, a common or single stepper based lithographic process, or a common or single holographic writing process.

The plurality of grating sections 42-1, 42-2, . . . are arranged on, the same, or the common active layer 24 which can easily be obtained by the common or single writing step to provide a fixed phase condition.

FIG. 1 exemplarily shows that the grating structure 40 comprises the two integrally formed grating sections 42-1, 42-2 arranged spatially adjacent to each other. The plurality of integrally formed grating sections 42-1, 42-2, . . . may be defined with a single grating writing field for manufacturing such as an e-beam grating writing system using an e-beam exposure field, a common stepper based lithographic process, or a common holographic writing process. The use of the single grating writing process ensures that the grating sections 42-1, 42-2, . . . are continuously written i.e. directly written in a single pass. This results in a pre-defined phase condition across the plurality of grating sections 42-1, 42-2, . . . directly written by the single grating writing field. More particular, using a single writing step may allow to precisely obtain the pre-defined phase condition in a manufactured device and for maintaining the pre-defined phase condition over a large number of manufactured devices, resulting in a high yield.

At least two of the grating sections 42-1, 42-1, . . . are spatially disjoint, i.e., they have no spatial overlap and have, by way of example, a common boundary or borderline.

In other words, the grating structure 40 comprises two or more spatially disjoint grating sections 42-1, 42-2, . . . arranged next to each other. The two or more spatially disjoint sections 42-1, 42-2, . . . may be integrally formed so that a specific phase condition is obtained across them. Therefore, arbitrary phases across the grating sections 42-1, 42-2, . . . of the grating sections 40, and consequently phase mismatches within the laser device 10, are avoided. This results in enhanced device yield and thus, improved array compatibility of the laser device 10.

The material of the semiconductor substrate 30 and the grating structure 40 may comprise at least one of InP, InGaAsP, InGaAs and other suitable materials.

The DFB structure 60-1 has a first grating section 42-1 of the grating structure 40 and the at least one DBR structure has a second grating section 42-2 of the grating structure 40.

The first grating section 42-1 and the second grating section 42-2 share the common active layer 24.

Possible embodiments of the invention may relate to a laser device comprising a DFB structure 60-1 and at least one DBR structure 60-2 meaning that the laser device may have a DFB structure and two DBR structures as will be exemplarily described in one of the figures in this disclosure, or a DFB structure and three DBR structures, or a DFB structure and more DBR structures.

Alternatively or additionally, a DFB structure may be configured to provide the optical function of the DFB structure as a lasing function. That is, any one DFB structure of the two DFB structures, or three DFB structures, or more DFB structures may provide a lasing function for a laser device and the other DFB structures of the two DFB structures, or three DFB structures, or more DFB structures may each provide a function of an optical reflector.

It is also feasible in an embodiment that only one DFB structure of the two DFB structures, or three DFB structures, or more DFB structures may exclusively provide a lasing function for a laser device.

It is thus feasible that in accordance with embodiments of the present inventive concept, the laser device may comprise a plurality of DFB structures and a plurality of DBR structures sharing a common active layer 24. Each of the plurality of DFB structures may have a grating section of the grating structure 40. Each of the plurality of DBR structures may have a grating section of the grating structure 40. The plurality of DFB structures and the plurality of DBR structures may be arranged so as to share the common active layer 24 being common for at least the plurality of integrally formed grating sections 42-1, 42-2, Additional structures may be arranged at or on the same common active layer 24 or a different, further active layer as part of the active layer structure 20.

In particular, FIG. 1 exemplarily shows the laser device 10 comprising the DFB structure 60-1 and the DBR structure 60-2. The DFB structure 60-1 comprises the first grating section 42-1 and the DBR structure 60-2 comprises the second grating section 42-2. The DFB structure 60-1 and the DBR structure 60-2 are arranged spatially adjacent to each other and share the common active layer 24 being common for the grating sections 42-1 of the DFB structure 60-1 and the second grating section 42-2 of the DBR structure 60-2.

Implementing the common active layer 24 may comprise a single e-beam or a stepper writing or a holographic writing, which may provide for a precise phase condition across the DFB structure 60-1 and the DBR structure 60-2 as there may be avoided a need of interfaces between different, joined active layers. By rendering it unnecessary to join different parts or sections of the active layer which could cause unwanted influences or deviations in the phase condition, the aimed or designed phase condition may be precisely obtained in a plurality of devices, thereby resulting in a high yield of a manufacturing process the laser device 10. The common active layer 24 of the laser device 10 may thereby be configured so as to maintain the specific phase condition across the DFB structure 60-1 and the DBR structure 60-2. This helps in further avoiding phase mismatches in the laser device 10 and reduces overall production costs.

It is also a feasible embodiment that a laser device of the present inventive concept may additionally be designed or optimized for allowing an uncooled operation.

The DFB structure 60-1 comprises a first associated optical function as a lasing function. That is, the DFB structure 60-1 may be configured to generate laser light. In other words, the DFB structure 60-1 is configured to permit a lasing action of the laser light provided by the common active layer 24. The at least one DBR structure 60-2 comprises a second associated optical function. The second associated optical function may comprise an optical feedback. In other words, the at least one DBR structure 60-2 may be configured to provide an optical feedback of the laser light. The optical feedback of the laser light may comprise reflection.

Although not explicitly shown in FIG. 1, the DFB structure 60-1 may be provided with structures enabling electrical activation of the DFB structure 60-1. The electrical activation i.e. electrical energization of the DFB structure may comprise biasing and/or modulating the DFB structure with electrical signals via an application of an electrical field, such as an injection current. Also not shown explicitly in FIG. 1, the at least one DBR structure 60-2 may be provided with structures enabling electrical activation of the at least one DBR structure 60-2. This electrical activation or electrical energization of the at least one DBR structure 60-2 may be optional. In other words, various embodiments of the inventive concept may relate to the at least one DBR structure 60-2, wherein to the at least one DBR structure 60-2 may be lacking structures enabling its electrical energization. In other words, the at least one DBR structure 60-2 may be configured to be unmodulated. Further, embodiments of the present invention wherein a laser device may comprise a plurality of DBR structures, at least one of the plurality of DBR structure may be provided with structures enabling electrical energization.

The laser device of FIG. 1 can act as a light emitting device. In particular, light may be emitted in response to electrical signals applied between the DFB structure 60-1 on the one hand and the semiconductor substrate 30 on the other hand. It is to be noted that although the laser device 10 according to FIG. 1 may be referred to as a dual DFB laser with a common active layer or a DFB+DBR laser with a common active layer, however it may have, in accordance with the present inventive concept, possibly multiple DFB structures and multiple DBR structures sharing a common active layer resulting in a multi-laser device with a common active layer.

According to an embodiment, the laser device 10 may comprise an electrode arrangement; wherein the DFB structure 60-1 may be arranged between a first pair of electrodes, wherein the first pair of electrodes is associated with the DFB structure 60-1 to adapt the optical function of the DFB structure 60-1 i.e. the lasing action of the DFB structure 60-1 Such electrodes may be used for applying an electrical field to the DFB structure 60-1 thereby activating or adjusting or modulating the optical field. Different pairs of electrodes may but are not required to have disjoint or separate electrodes. For example, different pairs of electrodes may share a common electrode such as a reference electrode, e.g., electrode 66-3 in FIG. 2.

According to an embodiment, the DFB structure 60-1 may be configured to obtain a first resonance having a first frequency of a carrier-photon resonance, CPR.

According to an embodiment, the laser device 10 may comprise the electrode arrangement, wherein the at least one DBR structure 60-2 may be arranged between a second pair of electrodes, wherein the second pair of electrodes is associated with the at least one DBR structure 60-2 to adapt the optical function of the at least one DBR structure 60-2.

According to an embodiment, the at least one DBR structure 60-2 may be configured to obtain a second resonance having a second resonance frequency of a photon-photon resonance, PPR.

In the following an illustrative example of the aspect of the inventive concept according to FIG. 1 is described in more detail. It is understood by persons skilled in the art that the following details are intended to illustrate only an example which does not limit many possible variations of the laser device 10.

For example, the DFB structure 60-1, and thus a portion of the common active layer 24 shared by the first grating section 42-1 of the grating structure 40, may be biased and modulated with the help of the electrode arrangement so as to provide the lasing action of the laser light provided by the active layer 24. The lasing action of the laser light may obtain the first resonance having the first frequency such as a carrier-photon resonance (CPR) having a carrier-photon resonance (CPR) frequency. The DBR structure 60-2, and thus a different portion of the common active layer 25 shared by the second grating section 42-2 of the grating structure 40, may be biased with the help of the electrode arrangement so as to provide optical feedback via reflection within the laser device 10.

The at least one DBR structure 60-2 may be electrically inactive, e.g., based on an absence of electrodes or other measures, i.e. the at least DBR structure 60-2 may be adapted such that the light emitted from the DFB structure 60-1 may permit optical transparency within the at least one DBR structure 60-2. This may allow the at least one DBR structure 60-2 to function as a possibly controllable Bragg grating section. Thus, optical emission due to the lasing action of the first DFB structure 60-1 i.e. the light which may be emitted from the DFB structure 60-1 may make the second DFB structure 60-2, and its comprising portion of the common active layer 24, optically transparent. The light emitted from the DFB structure 60-1 may compensate the losses in the at least one DBR structure 60-2 and thus makes the at least one DBR structure 60-2 transparent. This reduces absorption losses and results in significant reflection in the laser device 10.

Regardless of the electrical activation of the at least one DBR structure 60-2, the DBR structure 60-2 may be adapted to permit the second resonance having the second resonance frequency such as a photon-photon resonance, PPR, having a photon-photon resonance frequency. In particular, the DBR structure 60-2 may even be pumped electrically so as to obtain a specific value of the PPR frequency. The second resonance frequency may be higher than the first resonance frequency i.e. the PPR frequency may be higher than the CPR frequency. In other words, the mode associated with the PPR may be higher than the mode associated with the CPR. That is, the DBR mode may be adapted to be on the longer wavelength side of the DFB mode. Therefore, the laser device 10 may achieve a higher modulation speed owing to the higher PPR frequency allowed by the PPR effect.

Although not shown in FIG. 1, according to an embodiment, the laser device 10 may comprise a second DBR structure. The optical function of the second DBR structure may comprises a mode selection of the laser device. That is, the second DFB structure may select a frequency of the light provided by the common active layer 24 of the active layer structure 20.

In accordance with FIG. 1, the first facet 50-1 is arranged spatially adjacent to one end 28-1 of the active layer structure 20 and the second facet 50-2 is arranged spatially adjacent to an opposing end 28-2 of the active layer structure 20. The second facet 50-2 is opposite to the first facet 50-1. The first facet 50-1 is configured for emitting the laser light. It is also a feasible that instead of the first facet 50-1, the second facet 50-2 may be configured to emit the laser light. Hence, any one of the facets 50-1, 50-2 configured to emit light may form a front facet of the laser device 10 and the other facet may form a rear facet of the laser device 10. As can also be seen in FIG. 1, the facets 50-1, 50-2 may extend in a vertical direction, parallel to the y-axis, so as to cover laterally opposing side faces of the semiconductor substrate 30, laterally opposite side faces formed at the ends 28-1, 28-2 of the active layer structure 20 and laterally opposite side faces of the grating structure 40.

Each of the first facet 50-1 and the second facet 50-2 may comprise an anti-reflection (AR) coating 52. The AR coatings 52 mitigate the adverse effects of random phases being introduced to the laser light due to facet reflections. Thus, AR-coated facets 50-1, 50-2 support the maintenance of the pre-defined phase condition in the laser device 10 and may result high, e.g., at least 80%, at least 90% or higher, e.g., up to 100% single-mode yield device for high modulation speed applications, in combination with the PPR effect, ensuring array compatibility.

Alternatively, or additionally, any of the facets 50-1, 50-2 may be tilted longitudinally along a longitudinal projection, which may be at an angle to the z-direction. That is, at least one of the first facet 50-1 and the second facet 50-2 may be arranged so as to be tilted with a tilt angle. The tilt angle may be, for example, at least 7°, or at least 9° possibly within a tolerance range. The tilted, or sloping, facets may then avoid back-reflections in the laser device 10.

In other words, the facets 50-1, 50-2 may each comprise AR coatings 52 and any of these facets 50-1, 50-2 may be tilted, or sloping, with a tilt angle along a longitudinal projection, which may be at an angle to the z-direction. The AR coatings and tilt of the facets may then further avoid back-reflections. It is to be understood that any one facet of the facets 50-1, 50-2 comprising AR coating 52 may be tilted or both facets 50-1, 50-2 comprising AR coatings 52 may be tilted.

The material of the facets 50-1, 50-2 may be formed by sides of the layer stack of the device, not preventing possible further coatings.

The cladding structure 70 is configured for optically confining the laser light and is adapted such that the grating structure 40 is arranged between the active layer structure 20 and the cladding structure 70.

According to another embodiment, a conductivity type of the semiconductor substrate 30 may be opposite to a conductivity type of the cladding structure 70. For example, the conductivity type of the semiconductor substrate 30 may comprises n-type and the conductivity type of the cladding structure 70 may comprises p-type, or vice versa. The material of the cladding layer 70 may comprise at least one of a quaternary layer, InGaAs and InP cladding.

It is also to be understood that the semiconductor substrate 30, the cladding structure 70, the active layer structure 20, the facets 50-1, 50-2 and the grating structure 40 may extend longitudinally along a longitudinal projection, which may be parallel to the z-direction. This means that the semiconductor substrate 30, the cladding structure 70, the active layer structure 20 and the grating structure 40 may have equal longitudinally extending cross-sections in the x-z plane, perpendicular to the sectional view shown in FIG. 1. The facets 50-1, 50-2, owing to their vertical extension along the y-direction covering the side faces of the semiconductor substrate 30, the side faces defined by its ends 28-1, 28-2 of the active layer structure 20 and the side faces of the grating structure 40, may have longitudinally extending cross-sections in the y-z plane, perpendicular to the sectional view shown in FIG. 1.

After having described several embodiments of the present inventive concept with respect to FIG. 1, further embodiments of a laser device are described in connection with FIGS. 2 to 6. In particular, embodiments of the laser device 10 with varying realizations of the grating structure 40 and the active layer structure 20 are described.

FIG. 2 exemplarily shows a schematic cross-sectional view, parallel to the x-y plane, of a laser device 200 according to an embodiment. The laser device 200 may be formed in accordance with laser device 10. Details described herein in connection with FIG. 2 may be combined, with laser device 10.

The DFB structure 60-1 and the DBR structure 60-2 may be arranged so as to share portions of the cladding structure 70 and to partially cover the grating structure 40. Both the DFB structure 60-1 and the DBR structure 60-2 may be covered by a contact layer 74, different electrically separated parts of a same conductive layer respectively, the different parts having a conductivity type same as that of the DFB structure 60-1 and the DBR structure 60-2. Parts 74-1, 74-2 of the contact layer 74 may be arranged such that their lateral extension coincides with lateral extensions of the DFB structure 60-1 and the DBR structure 60-2 the parts 74-1, 74-2 of the contact layer 74 cover. That is, the first part 74-1 may extend laterally, at least within a tolerance range as wide as the first grating section 42-1 of the first DFB structure 60-1 and the second part 74-2 may extend laterally, at least within a tolerance range, as wide as the second grating section 42-2 of the DBR structure 60-2. For instance, the contact layer 74 may be formed of metal.

In particular, the laser device 200 may comprise the electrode arrangement, wherein the DFB structure 60-1 is arranged between a first pair of electrodes 66-1/66-3 and the at least one DBR structure 60-2 is arranged between a second pair of electrodes. Electrode 66-1 of the first pair of electrodes may be arranged partially covering the contact layer 74, e.g., part 74-1, such that the contact layer 74 is arranged between the DFB structure 60-1 and the electrode 66-1. Another electrode 66-2 of the second pair of electrodes comprising electrodes 66-2 and 66-3 may be arranged covering a part of contact layer 74, e.g., part 74-2 such that the contact layer 74 is arranged between the at least one DBR structure 60-2 and the another electrode 66-2. Each of the electrodes 66-1, 66-2 may have a lateral extension essentially or precisely coinciding with that of the corresponding parts 74-1, 74-2 of the contact layer 74.

It is also shown in FIG. 2 that the first and the second pair of electrodes may share a common electrode 66-3 arranged on a first face of the semiconductor substrate 30 facing away from the active layer structure 20. The common electrode 66-3 has a polarity opposite to those of the one electrode 66-1 and the another electrode 66-2. For example, the electrodes 66-1, 66-2 may be of p-type and the common electrode 66-3 may be of n-type. For another example, in contrast to the previously mentioned example, the electrodes 66-1, 66-2 may be of n-type and the common electrode 66-3 may be of p-type.

Sharing a common electrode among different pairs of electrodes may allow for a precise setting of voltages and/or avoidance of offsets between different pairs. Sharing a common voltage may also provide a common grounding terminal. However this does not exclude a configuration, where two or more pairs of electrodes do not share a common electrode, e.g., by segmenting electrode 66-3 which might allow for an increase of degrees of freedom for controlling device. A common electrode may further be used for more than two DBR structures. Alternatively or additionally, the electrode arrangement may be configured to provide electrical energization of the DFB structure 60-1. It may even be feasible that the electrode arrangement may be configured to exclusively provide electrical energization of the DFB structure 60-1.

Although the common electrode 66-3 is shown to be arranged adjacent to the substrate 30 on the first face whilst having segmented electrodes 66-1 and 66-2 on the other side of the common active layer 24, the arrangement may also be inverted, e.g., forming electrodes 66-1 and 66-2 as a common electrode and therefore segmenting electrode 66-3. It is also feasible that common electrodes may be arranged such that one of the common electrodes is adjacent to the substrate 30 and other of the common electrodes is adjacent to the cladding structure 70.

It is further feasible that the electrode arrangement may be adapted so as to have surface contacts arranged on a surface of the laser chip/device. Possibly, but not limiting to, or not exclusively, the semiconductor substrate may be isolated i.e. electrode-free. In particular, the electrode arrangement may be a surface electrode arrangement adapted to provide electrical energization and be arranged on a face of the cladding structure 70 facing away from the active layer structure 20. That is, the electrode arrangement may be implemented or realized on a surface of a laser device not adjacent to the substrate 30.

The electrodes may comprise spacings 68 for segmenting the electrodes from each other. It is illustrated in FIG. 2 that parts 74-1, 74-2 of the contact layer 74, and thus the segmented electrodes 66-1, 66-2 arranged adjacent to them, may be adapted to not extend laterally for the entirety of the lateral extension of the grating structure 40, wherein lateral extensions of the segmented electrodes 66-1, 66-2 may be segmented by the spacings 68.

In particular, as shown in FIG. 2, the first grating section 42-1 of the grating structure 40 within the first DFB structure 60-1 may comprise a first plurality of gratings 46-1. The first plurality of gratings 46-1 may be adapted to enable the optical function of the first DFB structure 60-1 i.e. the lasing action of the first DFB structure 60-1. The second grating section 42-2 of the grating structure 40 within the DBR structure 60-2 may comprise a second plurality of gratings 46-2. The second plurality of gratings 46-2 may be adapted to enable the optical function of the second DFB structure 60-2. For instance, grating characteristics of the grating sections 42-1, 42-2 such as any of grating periods, grating heights, grating shapes may be configured to operate the DFB structure 60-1 and the DBR structure 60-2.

Gratings of each of the grating sections may have an individual layout, e.g., adapted to the optical function of the DFB structure and/or the DBR section. For example, using a single writing step to form or produce the integrally formed grating sections may allow to easily form different grating sections or properties differently in different sections whilst maintaining a phase condition between different sections.

According to an embodiment, the plurality of integrally formed grating sections 42-1, 42-2, . . . may comprise a complex coupled grating and/or an index coupling grating.

According to an embodiment, grating periods of at least two of the plurality of integrally formed grating sections 42-1, 42-2, . . . may be equal to each other and coupling coefficients of the at least two grating sections 42-1, 42-2, . . . may be equal to each other.

According to an embodiment, grating periods of at least two of the plurality of integrally formed grating sections 42-1, 42-2, . . . may be different from each other and coupling coefficients of the at least two grating sections 42-1, 42-2, . . . may be different from each other. Such a configuration is depicted in FIG. 2 where, by way of non-limiting example only, the grating period of the first DFB structure 60-1 may be different from the grating period of the DBR structure 60-2. To be specific, a grating width of the first plurality of gratings 46-1 may be different from a grating width of the second plurality of gratings 46-2. It can also be seen in FIG. 2 that both the pluralities of gratings 46-1, 46-2 may have a same grating height. Variations of the grating sections 42-1, 42-2 having pluralities of gratings 46-1, 46-2 with different grating heights and/or equal grating widths are also feasible.

It is also seen in FIG. 2 that the grating heights of the grating sections 42-1, 42-2 may coincide with a height of the grating-free section 44. Alternatively, the height of the grating-free section 44 may be different to the grating height of at least one of the plurality of the grating sections 42-1, 42-2, . . . .

Further, the at least one of the pluralities of gratings 46-1, 46-2 of FIG. 2 may comprise complex coupled gratings. Additionally, or alternatively, at least one of the pluralities of gratings 46-1, 46-2 may comprise index coupled gratings.

According to an embodiment, the grating structure 40 may comprise at least one phase shift element 48, . . . forming a part of one of the grating sections 42-1, 42-2, . . . configured for applying a predefined phase shift to light travelling through the at least one phase shift element 48, . . . .

The first grating section 42-1, shown in FIG. 2, may comprise one phase shift element 48. Further phase shift elements or implementing grating section 42-1 without a phase shift element are not precluded. The phase shift element 48 may be adapted so as to obtain a phase shifting grating section. That is, the first grating section 42-1 may be a phase shifting grating section. The phase shift element 48 may have a width which is selected for obtaining a specific phase shift. The width of the phase shift element 48 may be larger than the grating widths of the first plurality of gratings of one or more of the grating sections. It is also feasible that the width of the phase shift element 48 may be smaller than the grating widths of the first plurality of gratings 46-1. Although any relationship may be implemented, advantageous optical relationships may be implemented when comparing the gratings of a grating section and of a phase shift element being a part thereof, e.g., λ/2, λ/4 or multiple of the wavelength such as 4λ, 3λ or 2λ.

According to an embodiment, and as shown in FIG. 2, each of the plurality of integrally formed grating sections 42-1, 42-2 may comprise a plurality of gratings 46 having a ridge waveguide structure or a buried heterostructure.

The laser device 200 may comprise a first waveguide layer, or buffer layer, 78 arranged between the semiconductor substrate 30 and the active layer structure 20. The laser device 200 may further comprise a second waveguide layer 80 arranged between the cladding structure 70 and the active layer structure 20 and may be configured for forming the grating structure 40. That is, the plurality of gratings 46 may be formed of the second waveguide layer 80.

However, it may also be an equally feasible embodiment of the present invention, in contrast to the illustration of FIG. 2, that the gratings 46 may be formed of the first waveguide layer 78 i.e. that the first waveguide layer 78 may be configured for forming the grating structure 40, instead of the second waveguide layer 80.

The first waveguide layer 78 and the second waveguide layer may extend laterally as wide as the faces 22, 23 of the active layer structure 20, possibly within a tolerance range. The second waveguide layer 80 may have a conductivity type opposite to that of the semiconductor substrate 30 and that of the first waveguide layer 78. That is, the first waveguide layer 78 may have a conductivity type which is same as that of the semiconductor substrate and opposite to that of the grating structure 40 and that of the cladding structure 70. For example, the first waveguide layer 78 may be of n-type and the second waveguide layer 80 may be of p-type. It is also possible that, for instance, the first waveguide layer 78 may be of p-type and the second waveguide layer 80 may be of n-type.

The embodiment of the laser device 200 shown in FIG. 2 may have the following physical and optical characteristics that are described by way of non-limiting examples and that shall not limit the scope of the present invention. Thus, the following characteristics and parameters are intended to illustrate an example. It is noted that the following characteristics and parameters do not limit the range of feasible parameters and possible variations thereof.

For example, the first DFB structure 60-1 may be a 120 μm long quarter wavelength shifted DFB having a coupling coefficient of 250 cm 1. This DFB structure may be optimized for an uncooled or a cooled operation. The second DFB structure 60-2 may be an active reflector with uniform grating, having the grating length 40 μm and the coupling coefficient of 250 cm 1, which may correspond to a reflection of about 58%. The common active layer 24 (CAL) may have a length of 160 μm. This example is one of a plurality of possible working examples not limiting the present invention.

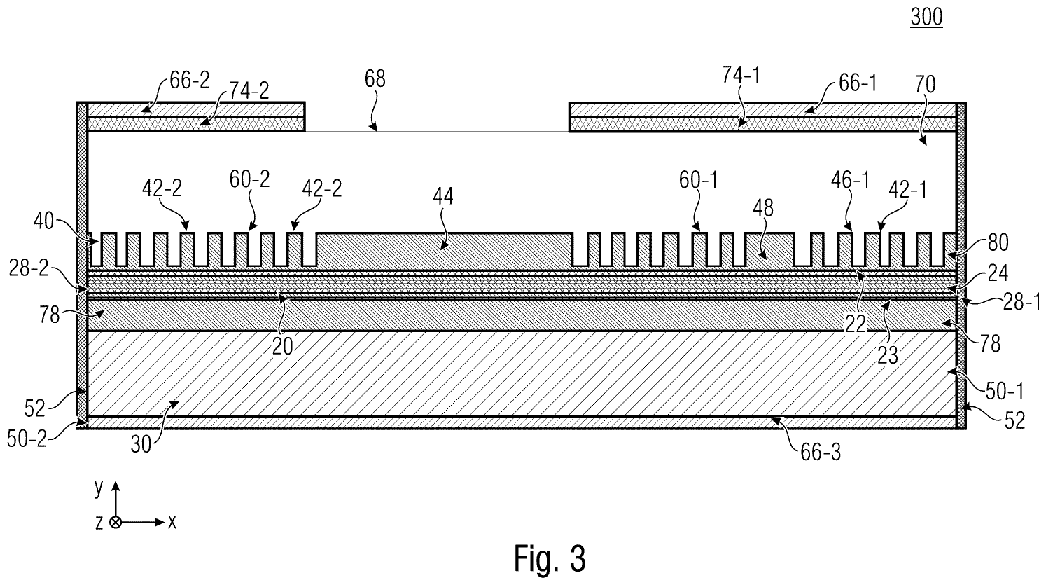

FIG. 3 exemplarily shows a schematic cross-sectional view, parallel to the x-y plane, of a laser device 300 according to an embodiment. The laser device 300 may be formed in accordance with laser device 10 and may be a variation of the laser device 200 as shown in FIG. 2. Details described herein in connection with FIG. 3 may be combined, with laser devices 10 and/or 200.

In accordance with an embodiment, the grating structure 40 may further comprise a grating-free section 44 configured for providing passive feedback of the laser light, wherein the grating-free section 44 is arranged between two grating sections 42-1, 42-2, . . . sharing the common active layer 24. That is, the grating-free section 44 and the plurality of grating sections 42-1, 42-2, . . . are arranged on the same common active layer 24.

In other words, the grating structure 40 comprises two or more spatially disjoint grating sections 42-1, 42-2, . . . arranged next to each other permitting at least the grating-free section 44, or possibly more grating-free sections, between any two grating sections of the plurality of grating sections 42-1, 42-2, . . . sharing the common active layer 24.

The grating-free section 44 and the plurality of grating sections 42-1, 42-2, . . . are arranged on, the same, or the common active layer 24 which can easily be obtained by the common or single writing step to provide a fixed phase condition. The plurality of integrally formed grating sections 42-1, 42-2, . . . and the grating-free section 44 may be defined with a single grating writing field for manufacturing such as an e-beam grating writing system using an e-beam exposure field. This results in a pre-defined phase condition across the plurality of grating sections 42-1, 42-2, . . . , and including the grating-free section 44, directly written by the single grating writing field.

The grating-free section 44 may be adapted to permit reflection of the laser light. The grating-free section 44 may be adapted to not obtain an optical gain of the laser light. In particular, a lateral extension of the grating-free section 44 may be selected to improve optical characteristics of the laser light. Such optical characteristics of the light may comprise, but not exclusively, reflection characteristics, absorption characteristics or transmission characteristics.

FIG. 3 exemplarily shows that the grating structure 40 comprises the two integrally formed grating sections 42-1, 42-2, each of which is arranged spatially adjacent to the grating-free section 44.

As shown in FIG. 3, the lateral extension of the grating-free section 44 may be larger than the lateral extension of any of the plurality of grating sections 42-1, 42-2, . . . . However, this does not preclude an implementation of a laser device comprising a grating free section between grating sections having a smaller lateral extension.

Although FIG. 3 illustrates that the grating structure 40 may comprise one or a single grating-free section 44, various embodiments may relate to a plurality of grating-free sections arranged, wherein each of the plurality of grating-free sections may be arranged, as a single grating-free section or in combination with at least one further grating-free section, between any two of the plurality of grating sections 42-1, 42-2, . . . of the grating structure 40 sharing the common active layer 24. In particular, the plurality of grating-free sections may be arranged adjacent to the plurality of grating sections 42-1, 42-2, . . . of the grating structure 40 sharing the common active layer 24 so as to obtain combinations of grating-free sections and grating sections 42-#, for example, an alternating combination of grating-free sections and grating sections 42-#.

The grating-free section 44 may be provided with electrical activation by arranging the grating-free section 44 with an electrode of the electrode arrangement such as described above in the present disclosure. The electrical energization of the grating-free section 44 may thus provide it with an associated optical function. That is, the grating-free section 44 may be pumped by a pumping means so as to obtain transparency. Alternatively, the grating-free section 44 may be configured to not be pumped.

It is emphasized that the grating-free section 44 may be integrally formed, in accordance with the plurality of integrally formed grating sections 42-1, 42-2, . . . comprised in the grating structure 40. Thus, the grating-free section may be adapted to not introduce unwanted phase mismatches due to attaching components to one another and may maintain the pre-defined phase condition across the DFB structures 60-1, 60-2, . . . .

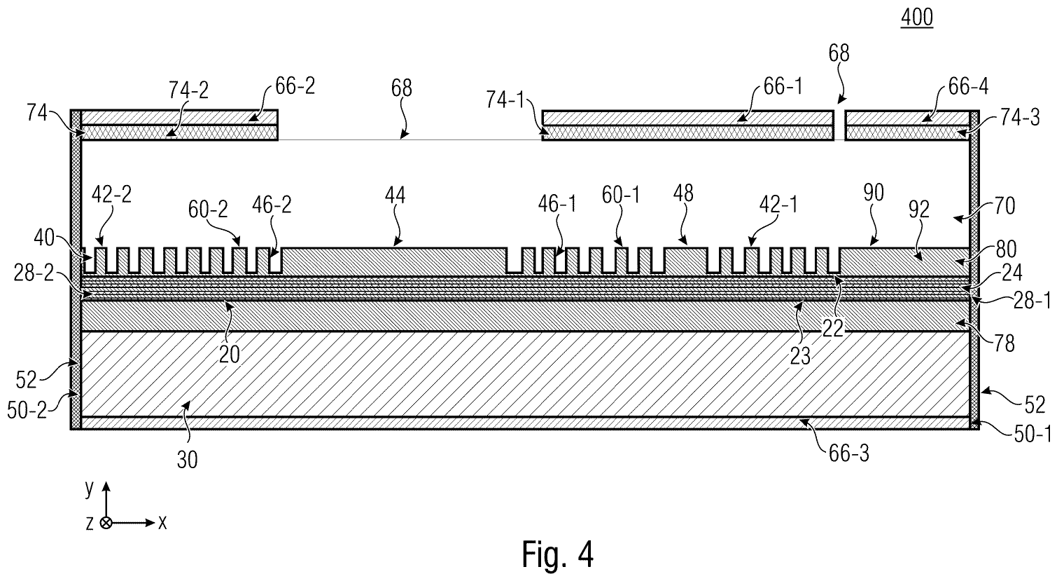

FIG. 4 shows a schematic cross-sectional view, parallel to the x-y plane, of a laser device 400 according to another embodiment. The laser device 400 may be formed in accordance with the laser device 10 as per the described aspect of the present inventive concept. Further, the laser device 400 may be a variation of the laser device 200, 300 and may additionally comprise at least one semiconductor optical amplifier, SOA, section 90 arranged on the common active layer 24 between the grating structure 40 and one of the facets 50-1, 50-2, wherein the SOA section 90 may be configured to modify an optical characteristic of the laser light i.e. the SOA 90 is configured to increase an output power of the laser light.

According to an embodiment, the laser device may further comprise at least one semiconductor optical amplifier, SOA, section 90 arranged on the common active layer 24 between the grating structure 40 and one of the facets 50-1, 50-2, the SOA 90 configured to modify an optical characteristic of the laser light i.e. the SOA 90 is configured to increase an output power of the laser light.

For instance, the SOA section 90 may be configured to obtain optical gain of an optical signal provided by the common active layer 24. In other words, the SOA section 90 may be adapted to amplify an optical signal provided by the common active layer 24, or the SOA section 90 may be configured by to boost/increase output power of light provided by the common active layer 24 by electrical pumping means.

In particular, FIG. 4 illustrates that one SOA section 90 may be arranged between the first DFB structure 60-1 and the first facet 50-1, the facet which may be configured to emit the laser light, sharing the common active layer 24. The SOA section 90 may comprise a non-grating section 92 arranged between the first grating section 42-1 and the first facet 50-1. That is, the non-grating section 92 of the SOA section 90 may be arranged between the cladding structure 70 and the active layer structure 20, in a vertical projection parallel to the y-direction.

In accordance with another feasible embodiment, the SOA section 90 may be arranged on the active layer structure 20 between the grating structure 40 and one of the facets 50-1, 50-2. That is, possibly, the SOA section 90 may be configured to not share the common active layer 24. For instance, the non-grating section 92 of the SOA section 90 may be arranged between the cladding structure 70 and a further active layer different from the common active layer as part of the active layer structure 20. This further active layer may be arranged adjacent to the common active layer 24 using, possibly including other processes and not exclusively, for instance, a butt-joint.

Additionally, or alternatively, the SOA section 90 may be arranged between the DBR structure 60-2 and the second facet 50-2, the facet which may be configured to emit the laser light instead of the first facet 50-1. In particular, the non-grating section 92 may be arranged between the second grating section 42-2 and the second facet 50-2. However, it is advantageous that the SOA section 90 may be arranged between the DBR structure 60-2 and any facet of the facets 50-1, 50-2, which is configured to emit light. That is, variation of the laser device 400 of FIG. 4 wherein the SOA section 90 is arranged adjacent to the DBR structure 60 and to the facet 50-2, which is configured to emit light instead of the facet 50-1, forms a viable embodiment.

Further embodiments provide for structures comprising two or more SOA sections, e.g., two SOA sections from which each may be arranged between one of the facets 50-1, 50-2 and ends of the grating structure 40. Possibly such a single SOA may be expanded by a further SOA.

Therefore, the SOA section 90 permits an improvement of the output optical power of the laser light emitted by a laser device in accordance with the inventive concept of the present disclosure.

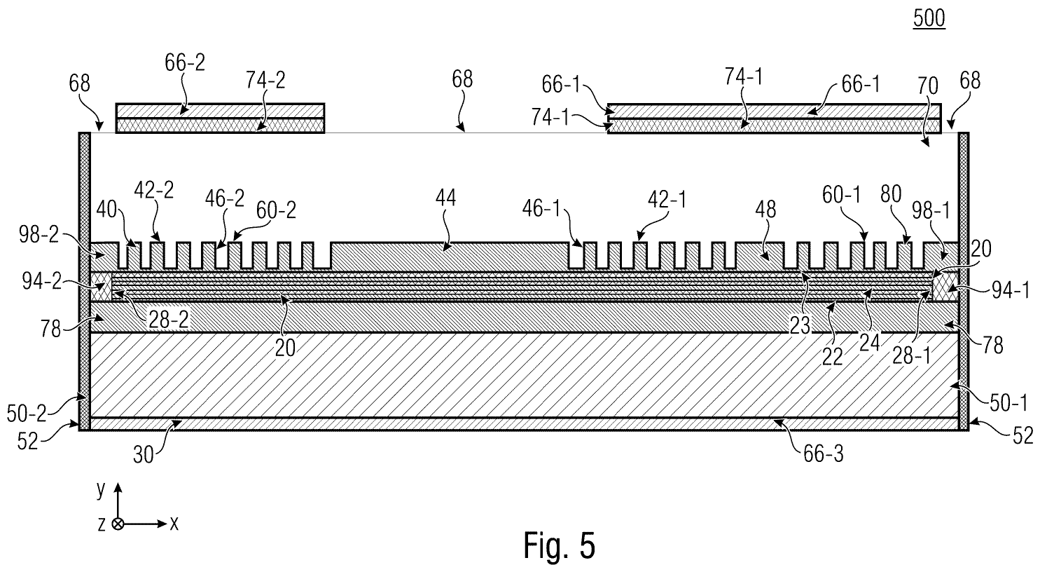

FIG. 5 shows a schematic cross-sectional view, parallel to the x-y plane, of a laser device 500 according to an independent aspect of the inventive concept. The laser device 500 may comprise the active layer structure 20 arranged between the semiconductor substrate 30 and the grating structure 40, wherein the active layer structure 20 may comprise the common active layer 24 formed to comprise aluminium. For example, the common active layer 24 may comprise InGaAlAs and thus comprises aluminium. The common active layer 24 is configured for a generation of laser light and the grating structure 40 is configured for manipulating the generation. The laser device 400 may further comprise the first facet 50-1 arranged spatially adjacent to end 28-1 of the active layer structure 20 and second facet 50-2 arranged spatially adjacent to opposing end 28-2 of the active layer structure 20. The first facet 50-1 may be configured for emitting the laser light, the second facet may be opposite to the first facet, and the first facet and the second facet 50-2 may comprise the anti-reflection coating 52.

The active layer structure 20 may comprises two integrated passive sections 94-1, 94-2 arranged spatially adjacent to opposing ends 28-1, 28-2 of the active layer 24, and the first facet 50-1 and the second facet 50-2. That is, in one embodiment the active layer structure 20 comprises exactly two integrated passive sections, e.g., formed as aluminium-free passive sections.

The Al-free passive sections 94-1, 94-2 may be adapted to provide spatial separation of the facet 50-1, 50-2 so as to minimize optical losses of the laser light. In particular, aluminium of the common active layer 24 may cause inducement of optical losses. Since aluminium has a high chemical affinity towards oxygen, the exposure of the Al-comprising common active layer 24 to air or an oxygen-rich environment via the facets 50-1, 50-2 may lead to unwanted oxidative processes leading to a disadvantageous reliability of the device. Hence, the integrated passive sections 94-1, 94-2 may provide a spatial disconnection of the common active layer 24 comprising Al with the facets 50-1, 50-2. In other words, the passive sections may enclose the ends 28-1, 28-2 of the common active layer 24 comprising Al so as to obtain aluminum-free facets 50-1, 50-2. Thus, the laser device 500 with the help of the integrated passive sections 94-1, 94-2 may permit an enhanced reliability of the device.

It is to be noted that the laser device 500 as shown in FIG. 5 may also be understood as an embodiment of the aspect of the invention described by FIGS. 1 to 4 In particular, the laser device 500 may be considered as a variation of the laser device according to previously described FIGS. 1-4.

As seen in FIG. 5, the first passive section 94-1 may be arranged adjacent to the first facet 50-1, the front facet or the facet which may be configured to emit light, and to the end 28-1 of the common active layer 24. The second passive section 94-2 may be arranged adjacent to the second facet 50-2, the rear facet or the facet which may be configured to not emit light, and to the end of 28-2 of the common active layer 24. The passive sections 94-1, 94-2 may cover the side faces of the active layer defined by its ends 28-1, 28-2 i.e. side faces of the passive section 94-1, 94-2 may extend longitudinally i.e. parallel to a z-direction along the longitudinal extension, or the length, of the common active layer 24.

Further, the Aluminium-free integrated passive sections 94-1, 94-2 may be arranged by forming butt-joints at the interfaces between the ends 28-1, 28-2 of the common active layer 24 and the facets 50-1, 50-2. The passive sections 94-1, 94-2 may be vertically surrounded by non-grating waveguide sections 98-1, 98-2 on one side and the waveguide layer 78 on the other side. As seen in FIG. 4, the non-grating waveguide section 98-1 may abut the first facet 50-1 and the first passive section 94-1 and the non-grating waveguide section 98-2 may abut the second facet 50-2 and the second passive section 94-2.

The material of the integrated passive sections may comprise at least one of InGaAsP, and other suitable materials.

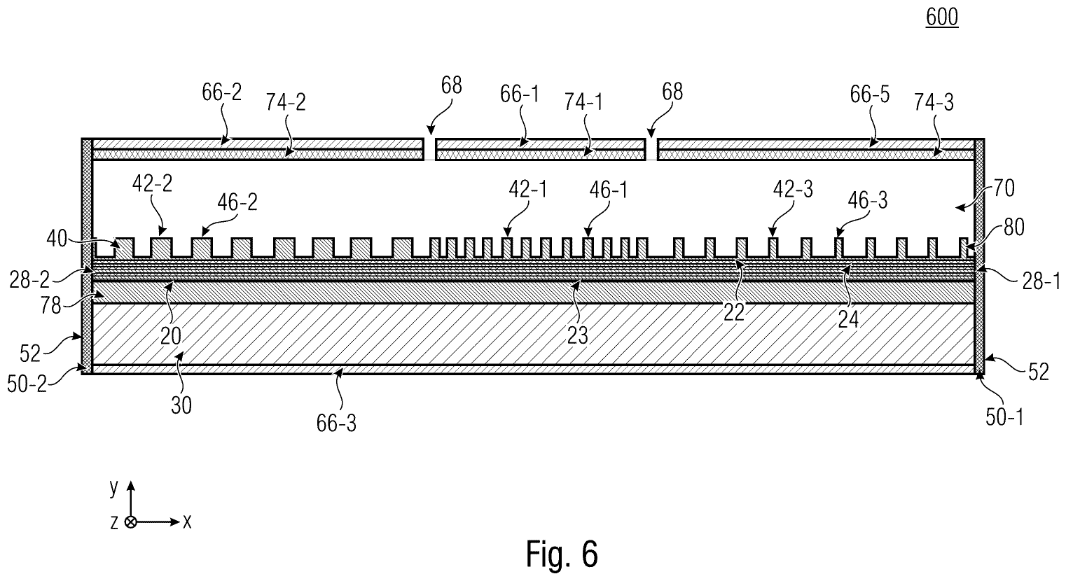

FIG. 6 exemplarily shows a schematic cross-sectional view, parallel to the x-y plane, of a laser device 600 according to an embodiment. The laser device 600 may be formed in accordance with laser device 10 and may comprise a DFB structure 60-1 and two DBR structures 60-2, 60-3 with their integrally formed grating sections 42-1, 42-2, 42-3 of the grating structure 40 sharing the common active layer 24. In FIG. 6 more than one DBR structure is implemented, e.g., two. Embodiments described in connection with other laser devices of the present disclosure may be implemented in the laser device 600 without limitation.

The DFB structure 60-1 may be arranged adjacent to the first DBR structure 60-2 on one side and to the second DBR structure 60-3 on other side. The second DBR structure 60-3 may be arranged between the DFB structure 60-1 and the first facet 50-1. The first DBR structure 60-2 may be arranged between the second facet 50-2 and the DFB structure 60-1.

The DFB structure 60-1 may have the first grating section 42-1, wherein the first grating section 42-1 may have a first grating period. The first DBR structure 60-2 may have the second grating section 42-2, wherein the second grating section 42-2 may have a second grating period. The second DBR structure 60-3 has the third grating section 42-3, wherein the third grating section 42-3 has a third grating period.

As seen in FIG. 6, the second grating period may, optionally, be larger than both the first grating period and the third grating period, and the first grating period may, optionally, be smaller than the third grating period. Other variations involving the grating periods of the grating sections 42-1, 42-2, 42-3 in comparison with each other may provide possible alternatives. As described earlier in the application, for instance, the first grating period, the second grating period and the third grating period may be equal to each other.

The plurality of gratings 46-2 of the second grating section 42-2 may have a grating width larger than that of the plurality of gratings 46-1 of the first grating section 42-1 and that of the plurality of gratings 46-3 of the third grating section 42-3. The grating width of the plurality of gratings 42-1 of the first grating section 42-1 may equal that of the plurality of gratings 42-3 of the third grating section 42-3.

The DFB structure 60-1 and each of the DBR structures 60-2, 60-3 may be arranged with their own respective pairs of electrodes 66-1/66-3, 66-2/66-3, 66-5/66-3.

In particular, the laser device 600 may comprise the electrode arrangement, wherein the DFB structure 60-1 is arranged between a first pair of electrodes 66-1/66-3, the first DBR structure 60-2 is arranged between a second pair of electrodes 66-2/66-3 and the second DBR structure 60-3 is arranged between a third pair of electrodes 66-5/66-3. Electrode 66-1 of the first pair of electrodes may be arranged partially covering the contact layer 74, e.g., part 74-1, such that the contact layer 74 is arranged between the DFB structure 60-1 and the electrode 66-1. Another electrode 66-2 of the second pair of electrodes comprising electrodes 66-2 and 66-3 may be arranged covering the at least a part of contact layer 74, e.g., part 74-2 such that the contact layer 74 is arranged between the first DBR structure 60-2 and the another electrode 66-2. Third electrode 66-5 of the third pair of electrodes comprising electrodes 66-5 and 66-3 may be arranged covering the at least a part of contact layer 74, e.g., part 74-3 such that the contact layer 74 is arranged between the second DBR structure 60-3 and the third electrode 66-3. Each of the electrodes 66-1, 66-2, 66-3 may have a lateral extension essentially or precisely coinciding with that of the corresponding parts 74-1, 74-2, 74-3 of the contact layer 74.

The DFB structure 60-1 and each of the DBR structures 60-2, 60-3 may comprise an associated optical function. For example, the laser device 600 may be a DFB+dual DBR laser device wherein the optical function of the DFB 60-1 may be a lasing action wherein the DFB may be configured to obtain a CPR having a CPR frequency, the optical function of the first DBR 60-2 may be a mode selection, e.g., implemented variably based on application of an optional electrical field, and the optical function of the second DBR 60-3 may comprise an optical feedback wherein the second DBR may be configured to obtain a PPR having a PPR frequency associated with the second DBR.

It is also possible that the optical functions of the first DBR 60-2 and the second DBR 60-3 may be exchanged. That is, the optical function of the second DBR 60-3 may comprise an optical feedback instead of the first DBR 60-1 and the optical function of the first DBR 60-1 then may comprise a mode selection instead of the second DBR 60-2.

Thus, the laser device 600 may have an enhancement of modulation bandwidth due to the PPR effect.

According to an embodiment, and as shown in FIGS. 2 to 6, each of the plurality of integrally formed grating sections 42-1, 42-2, may comprise a plurality of gratings 46 having a ridge waveguide structure or a buried heterostructure. The plurality of gratings 46 may be formed of a waveguide layer 80 having a conductivity type opposite to that of the semiconductor substrate 30.

Other embodiments of the invention are directed to a method for manufacturing a laser device and a method for generating laser light. Such methods may be implemented by the operation of the described devices.

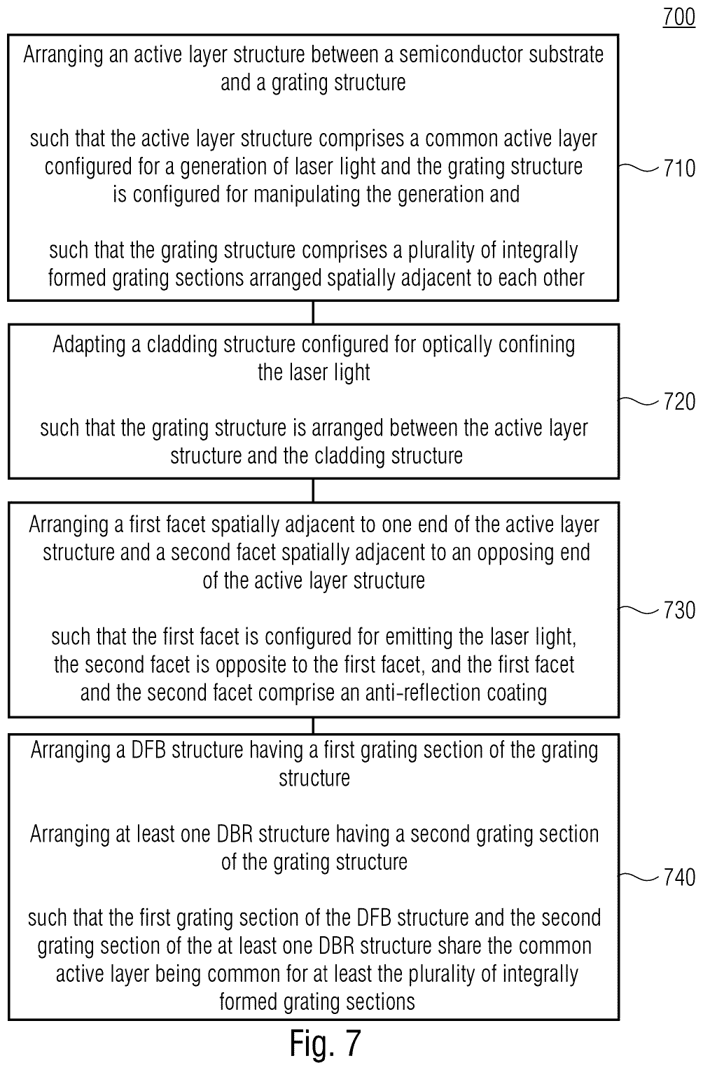

FIG. 7 shows a schematic block diagram relating to a method 700 for manufacturing a laser device according to embodiments of the invention. The method 700 comprising: a step 710 of arranging an active layer structure between a semiconductor substrate and a grating structure; such that the active layer structure comprises a common active layer configured for a generation of laser light and the grating structure is configured for manipulating the generation; and such that the grating structure comprises at plurality of integrally formed grating sections arranged spatially adjacent to each other, e.g., by writing the grating sections using a single or common E beam field, by writing the grating sections using a single or common stepper lithographic process, by writing the grating sections using a single or common holographic process; a step 720 of adapting a cladding structure configured for optically confining the laser light; such that the grating structure is arranged between the active layer structure and the cladding structure; a step 730 of arranging a first facet spatially adjacent to one end of the active layer structure and a second facet spatially adjacent to an opposing end of the active layer structure; such that the first facet is configured for emitting the laser light, the second facet is opposite to the first facet, and the first facet and the second facet comprise an anti-reflection coating; a step 740 of arranging a DFB structure having a first grating section of the grating structure and arranging at least one DBR structure having a second grating section of the DBR structure; such that the first grating section of the DFB structure and the second grating section of the at least one DBR structure share the common active layer being common for at least the plurality of integrally formed grating sections. This may provide a fixed phase condition when comparing different devices formed with the same process.

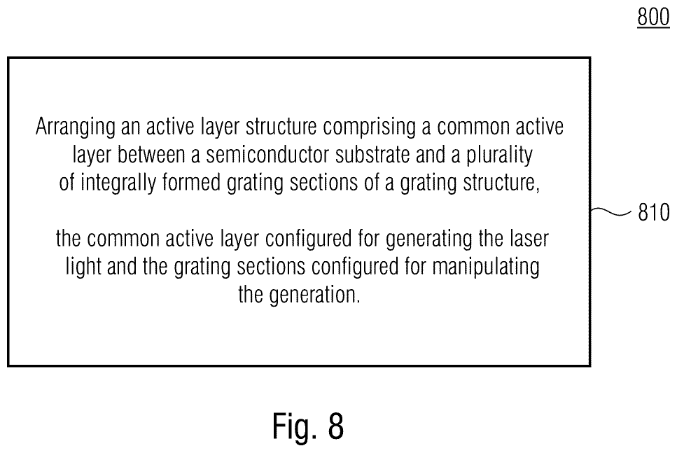

FIG. 8 shows a schematic block diagram relating to a method 800 for generating laser light according to embodiments of the invention. The method 800 comprising: a step 810 of arranging an active layer structure comprising a common active layer between a semiconductor substrate and a plurality of integrally formed grating sections of a grating structure, the common active layer configured for generating the laser light and the grating sections configured for manipulating the generation.

Embodiments according to the present disclosure relate to the following aspects:

Aspect 1 provides a laser device, comprising:
an active layer structure arranged between a semiconductor substrate and a grating structure, wherein the active layer structure comprises a common active layer configured for a generation of laser light and the grating structure is configured for manipulating the generation;
a first facet arranged spatially adjacent to one end of the active layer structure and a second facet arranged spatially adjacent to an opposing end of the active layer structure, wherein the first facet is configured for emitting the laser light, the second facet is opposite to the first facet, and the first facet and the second facet each comprise an anti-reflection coating;
wherein the grating structure comprises a plurality of integrally formed grating sections arranged spatially adjacent to each other;
a cladding structure configured for optically confining the laser light and adapted such that the grating structure is arranged between the active layer structure and the cladding structure;
a DFB structure having a first grating section of the grating structure,
at least one DBR structure having a second grating section of the grating structure,
wherein the first grating section and the second grating section share the common active layer being common for at least the plurality of integrally formed grating sections;
wherein the DFB structure comprises a first associated optical function as a lasing function and the at least one DBR structure comprises a second associated optical function.

Aspect 2 provides the laser device of aspect 1, wherein the grating structure further comprises a grating-free section configured for providing passive feedback of the laser light, wherein the grating-free section is arranged between two grating sections of the grating structure sharing the common active layer.

Aspect 3 provides the laser device of aspect 1 or 2, wherein the grating structure is obtained by a common or single writing process.

Aspect 4 provides the laser device of any of the previous aspects, wherein the grating structure comprises at least one phase shift element forming a part of one of the grating sections configured for applying a predefined phase shift to light travelling through the at least one phase shift element.

Aspect 5 provides the laser device of any of the previous aspects, wherein a conductivity type of the semiconductor substrate is opposite to a conductivity type of the cladding structure.

Aspect 6 provides the laser device of any of the previous aspects, comprising an electrode arrangement; wherein the DFB structure is arranged between a first pair of electrodes, wherein the first pair of electrodes is associated with the DFB structure to adapt the optical function of the DFB structure.

Aspect 7 provides the laser device of aspect 6, wherein the DFB structure is configured to obtain a first resonance having a first frequency of a carrier-photon resonance, CPR.

Aspect 8 provides the laser device of aspect 6 or 7, wherein the at least one DBR structure is arranged between a second pair of electrodes, wherein the second pair of electrodes is associated with the at least one DBR structure to adapt the optical function of the at least one DBR structure.

Aspect 9 provides the laser device of aspect 8, wherein the at least one DBR structure is configured to obtain a second resonance having a second resonance frequency of a photon-photon resonance, PPR.

Aspect 10 provides the laser device of any of aspects 8 or 9, comprising a second DFB structure; wherein the optical function of the second DFB structure comprises a mode selection of the laser device.

Aspect 11 provides the laser device of any of the previous aspects, wherein the active layer comprises at least one of an InGaAsP (QW)/InGaAsP (barrier) multi-quantum well, MQW, an InGaAlAs (QW)/InGaAlAs (barrier) MQW, an InGaAsP (QW)/InGaAlAs (barrier) MQW, InAs multi-quantum dot, MQD, and an InAs MQDash material.

Aspect 12 provides the laser device of any of the previous aspects, wherein each of the plurality of integrally formed grating sections comprise a complex coupled grating and/or an index coupling grating.

Aspect 13 provides the laser device of any of the previous aspects, wherein each of the plurality of integrally formed grating sections comprises a plurality of gratings having a ridge waveguide structure or a buried heterostructure.

Aspect 14 provides the laser device of any of the previous aspects, wherein grating periods of at least two of the plurality of integrally formed grating sections are equal to each other and coupling coefficients of the at least two grating sections are equal to each other.

Aspect 15 provides the laser device of the previous aspects, wherein grating periods of at least two of the plurality of integrally formed grating sections are different from each other and coupling coefficients of the at least two grating sections are different from each other.

Aspect 16 provides the laser device of any of the previous aspects, comprising at least one semiconductor optical amplifier, SOA, section arranged on the common active layer between the grating structure and one of the facets, the SOA configured to increase an output power of the laser light.

Aspect 17 provides the laser device of any of the previous aspects, wherein the semiconductor substrate comprises at least one of InP, GaAs, Si, SiC, SiNx and thin film lithium niobate.

Aspect 18 provides a laser device, comprising:
an active layer structure arranged between a semiconductor substrate and a grating structure, wherein the active layer structure comprises a common active layer formed to comprise aluminium (e.g., the common active layer comprising InGaAlAs), the common active layer is configured for a generation of laser light and the grating structure is configured for manipulating the generation;
a first facet arranged spatially adjacent to one end of the active layer structure and a second facet arranged spatially adjacent to an opposing end of the active layer structure, wherein the first facet is configured for emitting the laser light and the second facet is opposite to the first facet, and the first facet and the second facet comprise an anti-reflection coating; and wherein the active layer structure further comprises two integrated passive sections arranged spatially adjacent to opposing ends of the common active layer, and the first facet and the second facet.

Aspect 19 provides a method for manufacturing a laser device, the method comprising:
arranging an active layer structure between a semiconductor substrate and a grating structure;
such that the active layer structure comprises a common active layer configured for a generation of laser light and the grating structure is configured for manipulating the generation; and
such that the grating structure comprises at plurality of integrally formed grating sections arranged spatially adjacent to each other;
adapting a cladding structure configured for optically confining the laser light;
such that the grating structure is arranged between the active layer structure and the cladding structure;
arranging a first facet spatially adjacent to one end of the active layer structure and a second facet spatially adjacent to an opposing end of the active layer structure;
such that the first facet is configured for emitting the laser light, the second facet is opposite to the first facet, and the first facet and the second facet comprise an anti-reflection coating;
arranging a DFB structure having a first grating section of the grating structure;
arranging at least one DBR structure having a second grating section of the grating structure;
such that the first grating section of the DFB structure and the second grating section of the at least one DBR structure share the common active layer being common for at least the plurality of integrally formed grating sections.

Aspect 20 provides a method for generating laser light, the method comprising:
arranging an active layer structure comprising a common active layer between a semiconductor substrate and a plurality of integrally formed grating sections of a grating structure, the common active layer configured for generating the laser light and the grating sections configured for manipulating the generation.

Although some aspects have been described in the context of an apparatus, it is clear that these aspects also represent a description of the corresponding method, where a block or device corresponds to a method step or a feature of a method step. Analogously, aspects described in the context of a method step also represent a description of a corresponding block or item or feature of a corresponding apparatus.

While this invention has been described in terms of several embodiments, there are alterations, permutations, and equivalents which fall within the scope of this invention. It should also be noted that there are many alternative ways of implementing the methods and compositions of the present invention. It is therefore intended that the following appended claims be interpreted as including all such alterations, permutations and equivalents as fall within the true spirit and scope of the present invention.

### REFERENCES

[1.1] K. Nahakara et. al., “112-Gb/s PAM-4 Uncooled (25° C. to 85° C.) Directly Modulation of 1.3-μm InGaAlAs-MQW DFB BH Lasers with Record High Bandwidth”, ECOC 2020, paper PD2.4
[1.2] T. Hiraki et. al. “Uncooled Operation of Directly Modulated Membrane Laser with Buried Sapphire Layer on Si Substrate”, OFC 2024, paper Tu2D.3
[1.3] U. Troppenz, J. Kreissl, M. Möhrle, C. Bornholdt, W. Rehbein, B. Sartorius, I. Woods, M. Schell, “40 Gbit/s directly modulated lasers: physics and application,” Proc. SPIE 7953, Novel In-Plane Semiconductor Lasers X, 79530F (16 Feb. 2011)
[1.4] Gayatri Vasudevan Rajeswari, Martin Moehrle, Falco Ehrensack, Ute Troppenz, Ariane Sigmund, Martin Schell, “Novel >57 GHz bandwidth O-band InGaAlAs MQW RW DFB,” Proc. SPIE 12440, Novel In-Plane Semiconductor Lasers XXII, 1244007 (15 Mar. 2023)
[1.5] US20170256912A1
[1.6] Matsui, Y., Schatz, R., Che, D. et al. Low-chirp isolator-free 65-GHz-bandwidth directly modulated lasers. Nat. Photonics 15, 59-63 (2021).
[1.7] S. Yamaoka et. al. “Uncooled 100-GBaud Operation of Directly Modulated Membrane Lasers on High-Thermal-Conductivity SiC Substrate”, ECOC 2020, paper We1E.3
[1.8] N.-P. Diamantopoulos et al., “60 GHz Bandwidth Directly Modulated Membrane III-V Lasers on SiO2/Si,” in Journal of Lightwave Technology, vol. 40, no. 10, pp. 3299-3306, 15 May 15, 2022, doi: 10.1109/JLT.2022.3153648.
[1.9] G. Liu, G. Zhao, J. Sun, D. Gao, Q. Lu, and W. Guo, “Experimental demonstration of DFB lasers with active distributed reflector,” Opt. Express 26, 29784-29795 (2018).
[1.10] G. Vasudevan Rajeswari, M. Moehrle, A. Sigmund, M. Schell, “Dual DFB for Uncooled 40 Gbps and Cooled 72 Gbps Direct Modulation”, submitted to ISLC conference 2024.

1. A laser device, comprising:
an active layer structure arranged between a semiconductor substrate and a grating structure, wherein the active layer structure comprises a common active layer configured for a generation of laser light and the grating structure is configured for manipulating the generation;
a first facet arranged spatially adjacent to one end of the active layer structure and a second facet arranged spatially adjacent to an opposing end of the active layer structure, wherein the first facet is configured for emitting the laser light, the second facet is opposite to the first facet, and the first facet and the second facet each comprise an anti-reflection coating;
wherein the grating structure comprises a plurality of integrally formed grating sections arranged spatially adjacent to each other;
a cladding structure configured for optically confining the laser light and adapted such that the grating structure is arranged between the active layer structure and the cladding structure;
a DFB structure having a first grating section of the grating structure,
at least one DBR structure having a second grating section of the grating structure, wherein the first grating section and the second grating section share the common active layer being common for at least the plurality of integrally formed grating sections;
wherein the DFB structure comprises a first associated optical function as a lasing function and the at least one DBR structure comprises a second associated optical function as an optical feedback.

2. The laser device of claim 1, wherein the grating structure further comprises a grating-free section configured for providing passive feedback of the laser light, wherein the grating-free section is arranged between two grating sections of the grating structure sharing the common active layer.

3. The laser device of claim 1, wherein the grating structure is obtained by a common or single writing process.

4. The laser device of claim 1, wherein the grating structure comprises at least one phase shift element forming a part of one of the grating sections configured for applying a predefined phase shift to light travelling through the at least one phase shift element.

5. The laser device of claim 1, wherein a conductivity type of the semiconductor substrate is opposite to a conductivity type of the cladding structure.

6. The laser device of claim 1, comprising an electrode arrangement; wherein the DFB structure is arranged between a first pair of electrodes, wherein the first pair of electrodes is associated with the DFB structure to adapt the optical function of the DFB structure.

7. The laser device of claim 6, wherein the DFB structure is configured to obtain a first resonance having a first frequency of a carrier-photon resonance, CPR.

8. The laser device of claim 6, the at least one DBR structure is arranged between a second pair of electrodes, wherein the second pair of electrodes is associated with the at least one DBR structure to adapt the optical function of the at least one DBR structure.

9. The laser device of claim 8, wherein the at least one DBR structure is configured to obtain a second resonance having a second resonance frequency of a photon-photon resonance, PPR.

10. The laser device of claim 1, comprising a second DBR structure; wherein the optical function of the second DBR structure comprises a mode selection of the laser device.

11. The laser device of claim 1, wherein the common active layer comprises at least one of an InGaAsP (QW)/InGaAsP (barrier) multi-quantum well, MQW, an InGaAlAs (QW)/InGaAlAs (barrier) MQW, an InGaAsP (QW)/InGaAlAs (barrier) MQW, InAs multi-quantum dot, MQD and an InAs MQDash material.

12. The laser device of claim 1, wherein each of the plurality of integrally formed grating sections comprise a complex coupled grating and/or an index coupling grating.

13. The laser device of claim 1, wherein each of the plurality of integrally formed grating sections comprises a plurality of gratings having a ridge waveguide structure or a buried heterostructure.

14. The laser device of claim 1, wherein grating periods of at least two of the plurality of integrally formed grating sections are equal to each other and coupling coefficients of the at least two grating sections are equal to each other.

15. The laser device of claim 1, wherein grating periods of at least two of the plurality of integrally formed grating sections are different from each other and coupling coefficients of the at least two grating sections are different from each other.

16. The laser device of claim 1, comprising at least one semiconductor optical amplifier, SOA, section arranged on the common active layer between the grating structure and one of the facets, the SOA configured to increase an output power of the laser light.

17. The laser device of claim 1, wherein the semiconductor substrate comprises at least one of InP, GaAs, Si, SiC, SiNx and thin film lithium niobate.

18. A laser device, comprising:
an active layer structure arranged between a semiconductor substrate and a grating structure, wherein the active layer structure comprises a common active layer formed to comprise aluminium, the common active layer is configured for a generation of laser light and the grating structure is configured for manipulating the generation;
a first facet arranged spatially adjacent to one end of the active layer structure and a second facet arranged spatially adjacent to an opposing end of the active layer structure, wherein the first facet is configured for emitting the laser light and the second facet is opposite to the first facet, and the first facet and the second facet comprise an anti-reflection coating; and
wherein the active layer structure further comprises two integrated passive sections arranged spatially adjacent to opposing ends of the common active layer, and the first facet and the second facet.

19. A method for manufacturing a laser device, the method comprising:
arranging an active layer structure between a semiconductor substrate and a grating structure;
such that the active layer structure comprises a common active layer configured for a generation of laser light and the grating structure is configured for manipulating the generation; and
such that the grating structure comprises at plurality of integrally formed grating sections arranged spatially adjacent to each other;
adapting a cladding structure configured for optically confining the laser light;
such that the grating structure is arranged between the active layer structure and the cladding structure;
arranging a first facet spatially adjacent to one end of the active layer structure and a second facet spatially adjacent to an opposing end of the active layer structure;
such that the first facet is configured for emitting the laser light, the second facet is opposite to the first facet, and the first facet and the second facet comprise an anti-reflection coating;
arranging a DFB structure having a first grating section of the grating structure;
arranging at least one DBR structure having a second grating section of the grating structure;
such that the first grating section of the DFB structure and the second grating section of the at least one DBR structure share the common active layer being common for at least the plurality of integrally formed grating sections.

20. A method for generating laser light, the method comprising:
arranging an active layer structure comprising a common active layer between a semiconductor substrate and a plurality of integrally formed grating sections of a grating structure, the common active layer configured for generating the laser light and the grating sections configured for manipulating the generation.
